(19) United States
(12) Patent Application Publication
(10) Pub. No.: US 2006/0249200 A1
(43) Pub. Date: Nov. 9, 2006

(54) Polycrystalline silicon material for solar power generation and silicon wafer for solar power generation

(75) Inventors: Yasuhiro Kato, Tokyo (JP); Hiroshi Hagimoto, Tokyo (JP); Tatsuhiko Hongu, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignees: Sunric Co., Ltd., Tokyo (JP); Shin-Etsu Film Co., Ltd., Tokyo (JP)

(21) Appl. No.: 11/226,656

(22) Filed: Sep. 15, 2005

(30) Foreign Application Priority Data
Sep. 16, 2004 (JP) 2004-269274
Mar. 15, 2005 (JP) 2005-72683

(51) Int. Cl. C23C 16/00; H01L 31/00

(52) U.S. Cl. 136/258; 427/248.1

(57) ABSTRACT

A polycrystalline silicon material for solar power generation is polycrystalline silicon obtained by supplying a raw material silane gas to a red-hot silicon seed rod in a sealed reactor at high temperature to thereby thermally decompose or hydrogen-reduce the raw material silane gas. The polycrystalline silicon has a p-type or n-type conductivity, a resistivity of 3 to 500 Ωcm, and a lifetime of 2 to 500 μsec and is used for manufacturing a silicon wafer for solar power generation.

This application claims priority to prior Japanese patent applications JP 2004-269274 and JP 2005-72683, the disclosures of which are incorporated herein by reference.

### BACKGROUND OF THE INVENTION

This invention relates to a polycrystalline silicon material for solar power generation and a silicon wafer for solar power generation, and particularly to a stable supply of the polycrystalline silicon material and the silicon wafer.

As conventional manufacturing methods for high-purity polycrystalline silicon, the Siemens method and the monosilane method are predominant. In these methods, a silicon rod is stood upright in a sealed reactor and a raw material silane gas is introduced through a nozzle provided at the bottom of the reactor while heating the silicon rod to a high temperature so that polycrystalline silicon generated by thermal decomposition or hydrogen reduction of the raw material silane gas is deposited/grown on the silicon rod, thereby manufacturing polycrystalline silicon.

The raw material silane gas for use is a highly purified chlorosilane given by formula ClₙSiH₄₋ₙ (n is an integer of 0 to 4) and use is made of a monosilane, dichlorosilane, trichlorosilane, and tetrachlorosilane alone or as a mixture of two or more. The trichlorosilane (n=3) is mainly used in the Siemens method while the monosilane (n=0) is mainly used in the monosilane method. Silicon obtained by thermal decomposition or hydrogen reduction of the feed gas at high temperature has the same composition and purity as those of the silicon rod (hereinafter referred to as a “Si seed rod”) set in advance in the reactor and therefore the homogeneity and high purity are achieved from the center to the outer periphery. This silicon has the purity essential for the semiconductor industries and is thus referred to as semiconductor-grade polycrystalline silicon (SEG.Si).

Since the homogeneous high-purity polycrystalline silicon can be obtained by the Siemens method although it is the invention before the Second World War, the fundamentals thereof have not changed to date. A reaction formula in the case of trichlorosilane is given as the following formula (1).
SiHCl₃→(thermal decomposition)→p-Si (polycrystalline silicon) (1)

Quartz was used as a material of an initial reactor (bell jar) in the Siemens method. However, following an increase in demand for polycrystalline silicon, the reactor has increased in size for enhancing the productivity and, currently, use has been made of a metal bell jar made of a corrosion resistant metal, such as a carbon steel or a high nickel steel. Further, improvement has been implemented, such as mirror-finishing inner surfaces of a reactor or plating silver thereto, as means for uniformly and easily performing a temperature control in the reactor to prevent a loss of the reactor caused by heat radiation (see, e.g. JP-B-H06-41369; hereinafter referred to as “patent document 1”).

On the other hand, following the increase in size of the reactor, seed rods have increased in number and also in length and therefore the yield of high-quality high-purity products with a uniform diameter has decreased. As solving measures for improving uniformity and smoothness of a lot shape, various proposals have been made to date, such as an improvement in structure of a feed gas supply nozzle and an improvement in position and structure of an exhaust gas port (see, e.g. JP-A-H05-139891, JP-A-H06-172093, and JP-A-2001-294416; hereinafter referred to as “patent document 2”, “patent document 3”, and “patent document 4”, respectively) and a change in reaction conditions (see, e.g. JP-A-H11-43317; hereinafter referred to as “patent document 5”).

High-purity SEG.Si obtained by the Siemens method is used as a material for manufacturing a single crystal. A single crystal manufacturing method is the CZ (Czchoralski) method or the FZ (floating zone) method wherein a dopant such as P or B is added in the manufacture. The obtained single crystal is then sliced into IC wafers. The SEG.Si obtained by the Siemens method has an advantage in that high-purity products can be easily obtained, but also has a disadvantage in that since the diameter of a Si seed rod at the start is extremely thin like about 5 mm, the specific surface area thereof is small at the beginning of reaction and therefore the deposition rate is low. Therefore, it is understandable that if the productivity at the beginning of the reaction can be improved, it is possible to easily obtain inexpensive high-purity polycrystalline silicon.

In the monosilane method, a monosilane (SiH₄) is a material. In monosilane thermal decomposition, since no chlorine atoms exist in monosilane molecules, nearly 100% can be converted to silicon. However, in the case of vapor phase decomposition at a thermal decomposition temperature (600 to 850° C.), the monosilane becomes amorphous silicon powder and thus is not deposited/grown on the silicon seed rod. In order to achieve deposition/growth of silicon on the silicon seed rod like in the Siemens method, it is necessary to add a large amount of hydrogen.

Since the monosilane is used as the material, the polycrystalline silicon (SEG.Si) made by the monosilane method is free of chlorine contamination and thus has a higher purity than the SEG.Si of the Siemens method. Therefore, the SEG.Si of the monosilane method is mainly used as a material for manufacturing single-crystal silicon in the FZ method.

The FZ method is required to produce a product having a uniform diameter, containing no impurities such as insoluble powder, and having no bent portions and, therefore, various improvement techniques have been proposed therefor. For example, there have been proposed a technique of defining the gas flow rate in a reactor for the purpose of removing a laminar film staying around a heating filament in order to accelerate deposition of silicon (see, e.g. JP-A-S63-123806; hereinafter referred to as “patent document 6”), a technique of transferring a reactive gas along with silicon powder to a cooling wall of a powder catcher in order to prevent adhesion and mixing of insoluble powder (see, e.g. JP-A-H08-169797; hereinafter referred to as “patent document 7”), a technique of recirculating most of a reactive mixture, discharged from a silane decomposer, into a supply flow to the silane decomposer in order to achieve decomposition of a monosilane at the effective rate (see, e.g. JP-A-S61-127617; hereinafter referred to as “patent document 8”), and a technique of forming a bridge for connection between filament lines by the use of tantalum, molybdenum, tungsten, or zirconium having a low electrical resistance in order to prevent occurrence of high temperature during energization (see, e.g. JP-A-H03-150298; hereinafter referred to as “patent document 9”).

Monosilane is combustible and a large amount of hydrogen gas is used and, therefore, not only many safety devices are required attendant to handling thereof, but also the yield is low while the manufacturing cost is high.

On the other hand, various methods for exclusively manufacturing solar power generation (high-purity) silicon materials have been proposed and attempted to date. The final purpose thereof is to achieve the low cost and high quality. Particularly, an inexpensive and yet dedicated silicon material has been required for solar power generation. However, a dedicated material source has not been found.

Presently, silicon materials used in solar power generation rely on scraps/below-specification things (crystal head removal portions called tops, crystal bottom removal portions called tails, crystal side shavings, and the remains in a crucible) secondarily produced from the SEG.Si manufacturing process according to the foregoing Siemens method or monosilane method and scrap wafers secondarily produced from the wafer manufacturing process. However, not only there is a limit to the by-product scrap amount but also this amount tends to decrease in recent years and, therefore, how to stably secure the materials has been a big problem for the development of solar power generation.

In order to achieve the low cost, it is necessary that a starting material be inexpensive, and there have been many attempts. One of them is to refine metal silicon (MG.Si) or silicon secondarily produced from the semiconductor industries. For example, there are known a method of refining molten silicon by injecting a plasma jet gas to the surface thereof (see, e.g. JP-A-S63-218506, JP-A-H04-338108, and JP-A-H05-139713; hereinafter referred to as “patent document 10”, “patent document 11”, and “patent document 12”, respectively), a method of using a DC arc furnace (see, e.g. JP-A-H04-37602; hereinafter referred to as “patent document 13”), and a method of using an electron beam. There are further proposed many methods such as a method of refining silicon waste discarded from the semiconductor industries by unidirectional solidification processing (see, e.g. JP-A-H05-270814; hereinafter referred to as “patent document 14”), a method of refining molten silicon by adding an inert gas and an active gas or powder of CaO or the like to the molten silicon (see, e.g. JP-A-H04-16504 and JP-A-H05-330815; hereinafter referred to as “patent document 15” and “patent document 16”, respectively), and a method of refining MG.Si by placing it under reduced pressure to utilize a difference in boiling point (see, e.g. JP-A-S64-56311 and JP-A-H11-116229; hereinafter referred to as “patent document 17” and “patent document 18”, respectively). However, no satisfactory refining methods have been established that use those materials.

The reason why it is difficult to refine the molten silicon is that, although it is one factor that a silicon atom easily makes a stable compound with another element, it is difficult to remove p-type impurity B (boron) from silicon. Since a solid-liquid distribution (segregation) coefficient of B relative to Si is 0.81 close to 1, it is not possible to separate/purify B by a solid-liquid separation method such as unidirectional solidification. Even by the use of the difference in boiling point, the entrainment of the gas, or the like, it is difficult to completely process the whole molten substances.

The only method of purifying B is that, after reacting “metal silicon” with “hydrochloric acid” to obtain a silane gas, chlorinated boron obtained by a reaction of B+HCl is separated/purified by distillation or adsorption. The refined silane gas free of impurities is then reduced to high-purity SEG.Si, i.e. SEG.Si of the Siemens or monosilane method. Each method consumes much energy in the manufacturing process because of batch production and the SEG.Si obtained thereby is too expensive as described before so that it is problematic to use the same as a material for solar power generation.

As described above, gasification and then separation and removal by distillation is the most reliable method for removing the impurity B. Through the gasification, the other impurity elements dissolved in Si are also chlorinated (liquefied) and, therefore, the raw material silane gas is purified/refined by the distillation.

As a method of obtaining polycrystalline silicon by the use of a material purified by gasification other than the foregoing Siemens or monosilane method, there is a method using a fluidized bed reaction. In an external heating reactor, a refined raw material silane and a hydrogen gas are supplied from a lower part of the reactor to cause Si particles in the reactor to flow so as to deposit/grow silicon, thereby obtaining polycrystalline silicon and, after the reaction, the gas is discharged from an upper part of the reactor (see, e.g. JP-A-S57-145020, JP-A-S57-145021, and JP-A-H08-41207; hereinafter referred to as “patent document 19”, “patent document 20”, and “patent document 21”, respectively). The purity is 6 nines (99.9999%) or more and thus satisfies the grade for solar power generation.

In this conventional method, since the Si particles are used in place of the Si seed rod, the silicon deposition area increases. As a result, the silicon deposition/growth rate increases to enable continuous reactions so that high-purity silicon can be obtained at a low price. However, because of the external heating type, Si is deposited/grown even on an inner surface of a reaction pipe so that the continuous reactions cannot be continued and, further, the reaction pipe increases in size, which prevents this method from being put to practical use to date.

As another method of obtaining polycrystalline silicon by the use of a purified silane gas and a hydrogen gas, there is a vapor to liquid deposition method (see, e.g. JP-A-S54-124896, JP-A-S59-121109, JP-A-2002-29726, and JP-A-2003-54933; hereinafter referred to as “patent document 22”, “patent document 23”, “patent document 24”, and “patent document 25”, respectively). Since the thermal decomposition temperature is a melting point (1410° C.) or more of silicon, reduced/grown polycrystalline silicon is obtained in a molten state.

The foregoing method can be roughly divided into a “silicon deposition/melting zone” and a “zone for cooling deposited/melted silicon flowing downstream to obtain crystals” and is characterized by continuous reactions. Since the reaction temperature is high in the deposition/melting zone, there is a problem of purity caused by blocking at a material supply end portion and a material of a reactor. On the other hand, in the crystal receiving zone, not only it is difficult to quantitatively take out product silicon from the sealed system to the outside of the reaction system, but also contamination from members in that event is expected. Further, it is necessary to overcome many barriers for achieving practical use, such as a sealing structure between the “deposition/melting zone” and the “crystal receiving zone” as a hydrogen leakage prevention measure.

On the other hand, there have been proposed a method of using, in place of the Si seed rod used in the Siemens method, a seed rod made of a metal having a recrystallization temperature of 1100° C. or more, such as Mo (recrystallization temperature: 1200° C.), W (1350° C.), Ta (1200° C.), and Nb (1100° C.) (see, e.g. JP-A-S47-22827; hereinafter referred to as “patent document 26”) and a method, made by the present inventors, of using a seed rod made of an alloy such as Re-W (1500-1650° C.), W-Ta (1500-1650° C.), Zr-Nb (1200-1300° C.), TZM (Titanium-Zirconium-Molybdenum: 1250-1350° C.), or TEM™ (1200-1450° C.) as a member having a crystallization temperature of 1100° C. or more (as described in Japanese patent application No. 2004-184092 which is not yet published). These methods each aim at the seed rod and do not use it as a heat source. SEG.Si or SOG.Si obtained by using such a seed rod has a disadvantage in that since the seed rod should be removed by some method after completion of the reaction, another process is additionally generated.

From the foregoing, the method of using the gasified and refined material is prominent for obtaining high-purity polycrystalline silicon. The difference between a semiconductor material and a solar power generation material is a purity level, i.e. the former requires 11 nines (11 N) while the latter may be 6 nines (6N: 99.9999%), lower than the former by five digits, or more. Therefore, it is understandable that if a method can be developed that can satisfy the target purity of the latter and enables a stable supply of the latter at a price much lower than that of the former, it can be a “dedicated source for the solar power generation material”.

### SUMMARY OF THE INVENTION

It is an object of this invention to provide a polycrystalline silicon material for solar power generation that makes it possible to inexpensively and stably obtain polycrystalline silicon satisfying a purity suitable for a solar power generation material by the use of the Siemens method or the monosilane method.

It is another object of this invention to provide a method of manufacturing such a polycrystalline silicon material for solar power generation.

It is still another object of this invention to provide a silicon wafer for solar power generation using such a polycrystalline silicon material for solar power generation.

It is yet another object of this invention to provide a method of manufacturing such a silicon wafer for solar power generation.

According to one aspect of the present invention, there is provided a polycrystalline silicon material for solar power generation. The polycrystalline silicon material is composed polycrystalline silicon made by supplying a raw material silane gas to a heated (red-hot) silicon seed rod in a sealed reactor at high temperature to thereby thermally decompose or hydrogen-reduce said raw material silane gas. The polycrystalline silicon has a p-type or n-type conductivity, a resistivity of 3 to 50 Ωcm, and a lifetime of 2 to 500 μsec and being used for manufacturing a silicon wafer for solar power generation.

According to another aspect of the present invention, there is provided a silicon wafer for solar power generation. The wafer comprises a wafer manufactured by crystallizing the polycrystalline silicon material for solar power generation, without adding a doping agent and then slicing it.

According to still another aspect of the present invnetion, there is provided a method of manufacturing a polycrystalline silicon material for solar power generation. The method comprises the step of supplying a raw material silane gas to a heated silicon seed rod in a sealed reactor at high temperature to thereby thermally decompose or hydrogen-reduce said raw material silane gas. The polycrystalline silicon has a p-type or n-type conductivity, a resistivity of 3 to 500 Ωcm, and a lifetime of 2 to 500 μsec and is used for manufacturing a silicon wafer for solar power generation.

According to yet another aspect of the present invnetion, there is provided a method of manufacturing a silicon wafer for solar power generation. The method comprises the step of crystallizing the polycrystalline silicon made in the above-mentioned method without adding a doping agent and then slicing it, thereby manufacturing a wafer.

According to a further aspect of the present invnetion, there is provided a method of manufacturing a polycrystalline silicon material for solar power generation. The metod comprises the steps of using the silicon seed rod is made of any one of the polycrystalline silicon material above described, a heating type of an internal heating type, a heat source made of a metal, and an alloy, or a high-purity graphite having a recrystallization temperature of 1100° C. or more, when manufacturing the polycrystalline silicon by supplying the raw material silane gas to the heated silicon seed rod in the sealed reactor at the high temperature to thereby thermally decompose or hydrogen-reduce the raw material silane gas.

### DESCRIPTION OF THE PREFERRED EMBODIMENT

This invention will be described in detail.

A polycrystalline silicon material for solar power generation of this invention is composed of polycrystalline silicon made by supplying a raw material silane gas to a heated or red-hot silicon seed rod in a sealed reactor at high temperature, thereby thermally decomposing or hydrogen-reducing the raw material silane gas. The obtained polycrystalline silicon has a p-type or n-type conductivity, a resistivity of 3 to 500 Ωcm, and a lifetime of 2 to 500 μsec and is used for manufacturing a silicon wafer for solar power generation.

In this invention, the foregoing silicon seed rod is preferably made of polycrystalline silicon obtained from the foregoing polycrystalline silicon material for solar power generation, single-crystal silicon obtained from the foregoing polycrystalline silicon material for solar power generation by the use of the CZ or FZ method, or polycrystalline silicon obtained from the foregoing polycrystalline silicon material for solar power generation by the use of the casting method.

The foregoing raw material silane gas is a trichlorosilane or a monosilane and the concentration of boron in the silane gas is not less than 10 ppb and not more than 1000 ppb, preferably not more than 500 ppb.

A silicon wafer for solar power generation of this invention is a wafer manufactured by crystallizing the foregoing polycrystalline silicon material for solar power generation without adding a doping agent and then slicing it.

The silicon wafer for solar power generation of this invention is manufactured by slicing single-crystal silicon or polycrystalline silicon. The single-crystal silicon is made by the CZ or FZ method as a crystallization method. The polycrystalline silicon is made by the casting method as a crystallization method.

In the silicon wafer for solar power generation of this invention, the single-crystal or polycrystalline silicon wafer has a p-type or n-type conductivity and a resistivity or specific resistance of 0.3 to 10 Ωcm.

In manufacturing the polycrystalline silicon material for solar power generation of this invention, a raw material silane gas is supplied to a heated silicon seed rod in a sealed reactor at high temperature so as to be thermally decomposed or hydrogen-reduced, thereby obtaining polycrystalline silicon. The obtained polycrystalline silicon has a p-type or n-type conductivity, a resistivity of 3 to 500 Ωcm, and a lifetime of 2 to 500 μsec and is used for manufacturing a silicon wafer for solar power generation.

It is preferable to use, as the silicon seed rod, polycrystalline silicon made from the polycrystalline silicon material for solar power generation, single-crystal silicon made from the polycrystalline silicon material for solar power generation by the use of the CZ or FZ method, or polycrystalline silicon made from the polycrystalline silicon material for solar power generation by the use of the casting method.

In the method of manufacturing the polycrystalline silicon material for solar power generation, the raw material silane gas is a trichlorosilane or a monosilane and the concentration of boron in the silane is preferably not less than 10 ppb and not more than 1000 ppb, preferably not more than 500 ppb.

In manufacturing the silicon wafer for solar power generation of this invention, the polycrystalline silicon obtained in the foregoing method of manufacturing the polycrystalline silicon material for solar power generation is crystallized without adding a doping agent and then sliced, thereby manufacturing a wafer.

Further, in the method of manufacturing the silicon wafer for solar power generation, it is preferable that the wafer may be made by slicing single-crystal silicon or polycrystalline silicon. The single-crystal silicon is made by the CZ or FZ method as a crystallization method. The polycrystalline silicon is made by the casting method as a crystallization method.

Further, in the method of manufacturing the silicon wafer for solar power generation, it is preferable that the obtained single-crystal or polycrystalline wafer has a p-type or n-type conductivity and a resistivity of 0.3 to 10 Ωcm.

In manufacturing the polycrystalline silicon material for solar power generation of this invention, when manufacturing the polycrystalline silicon by supplying the raw material silane gas to the heated silicon seed rod in the sealed reactor at the high temperature to thereby thermally decompose or hydrogen-reduce the raw material silane gas, the heating type is an internal heating type, a heat source is made of a metal, an alloy, or a high-purity graphite having a recrystallization temperature of 1100° C. or more. The silicon seed rod is made of the single crystalline silicon or the polycrystalline silicon. The polycrystal silicon is made from the polycrystalline silicon material for solar power generation or is made from the polycrystalline silicon material for solar power generation by the use of the casting method. The single-crystal silicon is made from the polycrystalline silicon material for solar power generation by the use of the CZ or FZ method. Although the normal external heating type can also be adopted, the internal heating type is better in power source unit required for the manufacture. Further, it is preferable to use a seed rod having a p-type or n-type depending on a final cell specification and having a resistivity of 3 to 500 Ωcm and a lifetime of 2 to 500 μsec.

It is preferable that the raw material silane gas be supplied after having cooled the foregoing heat source to 900° C. or less, preferably 800° C. or less.

This invention relates to the method of supplying the raw material silane gas to the heated Si seed rod in the sealed reactor at the high temperature and depositing/growing the polycrystalline silicon made by thermal decomposition or hydrogen reduction of the raw material silane gas. Except that “Si seed rod purity-kind” and “material purity” are adapted for use in solar batteries, known methods/conditions in this industry can be adopted for various methods/conditions, such as a material and structure of a reactor, a method for connection between a Si seed rod and an electrode holder and a method for arrangement of them in the reactor, a power circuit connection method, a method of preventing contact with adjacent members, a method of improving an ingot surface condition, a mixing ratio and flow rate of a silane gas and a hydrogen gas, and a reaction temperature and time. Therefore, a large amount of a polycrystalline silicon material for solar power generation can be inexpensively manufactured without adding any particular means. Further, by crystallizing the obtained feed polycrystalline silicon “without adding a dopant” and then slicing it, wafers for solar power generation can be inexpensively manufactured.

Now, this invention will be described in further detail.

Since the final use of SEG.Si of the Siemens or monosilane method is for IC, high-purity silicon with no impurities is used for the Si seed rod. On the other hand, in this invention, either single-crystal silicon or polycrystalline silicon can be used for the Si seed rod and it is sufficient that the quality thereof only satisfies the purity for solar power generation, which is the final target, and therefore, inexpensive one can be used. It is preferable to reuse, as the seed rod, the polycrystalline silicon obtained by the method of this invention, the single-crystal silicon obtained from the polycrystalline silicon material for solar power generation by the use of the CZ or FZ method according to the method of this invention, or the polycrystalline silicon obtained from the polycrystalline silicon material for solar power generation by the use of the casting method according to the method of this invention, which is advantageous in terms of the price.

The method of manufacturing a polycrystalline silicon material according to the Siemens method has a problem that, mainly because of the external heating type, not only it is difficult to increase the size of an apparatus but also the manufacturing cost increases due to a heat loss. On the other hand, in this invention, the internal heating type is employed, the heat source is made of the metal, alloy, or high-purity graphite having the recrystallization temperature of 1100° C. or more, and the seed rod for Si deposition is made of the polycrystalline silicon obtained in this invention, the single-crystal silicon manufactured by the CZ or FZ method using the polycrystalline silicon obtained in this invention, or the polycrystalline silicon manufactured by the casting method using the polycrystalline silicon obtained in this invention. Therefore, not only it is possible to increase the size of an apparatus but also the heat loss is small and the cost is low. It is preferable to use the seed rod having a p-type or n-type depending on a final cell specification and having a resistivity of 3 to 500 Ωcm and a lifetime of 2 to 500 μsec.

As the metal or alloy having the recrystallization temperature of 1100° C. or more, it is possible to cite Mo, W, Ta, Nb, Re—W, W—Ta, Zr—Nb, or TZM (Ti, Zr, C). However, it is preferable to use lanthanum (La)-doped Mo, so-called TEM on the market, which is not subjected to hydride or silicide formation even in the presence of a hydrogen gas and a silane gas at high temperature and is free of brittle degradation. It is preferable that the ash content of the high-purity graphite be 5 ppm or less.

As the reaction of decomposition of the raw material silane gas proceeds, Si is deposited on the surfaces of members used as the heat source. Therefore, before supplying the raw material silane gas, the surface temperature of these members is cooled to 900° C. or less, preferably 800° C. or less, so that the deposition of Si can be prevented. There is a merit that the members that can prevent the deposition of Si can be reused as heat source members. Another merit of cooling to 900° C. or less resides in that hydride formation due to the hydrogen gas can be suppressed. However, the cooling is not necessarily required in disregard of the total cost. Assuming a large-size reactor, the number of heat source members and arrangement thereof in the reactor can be properly selected and are not limited irrespective of the center of the reactor.

A trichlorosilane is thermally decomposed at 950 to 1200° C. and a monosilane at 600 to 850° C. The obtained “polycrystalline silicon” is crushed to pieces called nuggets each having a size of 20 to 100 mm so as to serve as a material of “single-crystal silicon” of the CZ method or “polycrystalline silicon” of the casting method. Alternatively, the obtained “polycrystalline silicon” is used as a material of the FZ method as it is in a rod shape without being crushed so as to be formed into “single-crystal silicon” which is then sliced into solar cell wafers for solar power generation.

It is understandable that if an inexpensive material (low-purity silane) is used and the obtained polycrystalline quality satisfies the polycrystalline silicon purity for solar power generation, it is possible to obtain a polycrystalline silicon material that is inexpensive and dedicated for solar power generation.

The price of a silane material is proportional to its purity. The purity is determined based on the concentration of B (boron) contained in the silane and thus the price is inversely proportional to the content of B. The content of B in a semiconductor-grade silane is ppb level being zero or less and, in the case of a chemical grade, it is ppm level to percent (%) level. There is a difference of three digits or more even at minimum and the price of the latter is low.

Since use is made of a trichlorosilane with the content of B on ppb level being zero or less, the purity of the polycrystalline silicon obtained in the Siemens method is the high purity of SEG.Si (11N: 11 nines). Although the accuracy is influenced by an analytical method on this level, the standard quality is such that the total of general six elements of Fe, Cu, Ni, Cr, Zn, and Na is 5 ppb or less (measurement method: ICP method), the donor amount of Al (aluminum) and B is 0.1 ppb or less (measurement method: photoluminescence method), the resistivity in n-type is 1000 Ωcm or more (measurement method: four-terminal method), and the lifetime is 1000 μsec or more (measurement method: ASTM F28-91).

The general refining method for a raw material silane is distillation. For example, the concentration of B in a coarse trichlorosilane before distillation reaches several thousand ppb and, by increasing a cutting rate of low boiling point substances to thoroughly cut the content of B, the coarse trichlorosilane is purified to one-digit ppb level or less. However, since polycrystalline silicon obtained by thermal decomposition of a silane is contaminated with B contained in a reactor, although it is possible to reduce B to near zero, it is not possible to reduce B to zero. The concentration of B in the raw material silane for use in this invention is preferably not less than 10 ppb and not more than 1000 ppb, preferably not more than 500 ppb. The reason is that the concentration of B less than 10 ppb is required for semiconductor but is comparatively expensive for solar power generation. The upper limit is influenced by the content of the other metals that are contained in feed MG.Si and adversely affect the solar power generation efficiency. However, although there is an acceptable case even with the concentration of B being more than 1000 ppb, the level that can stably maintain the photoelectric conversion efficiency regardless of a kind of material, contamination of an apparatus, and so on is 1000 ppb or less, preferably 500 ppb or less.

On the other hand, the purity of MG.Si used in manufacturing silicone resin is 98 to 99% (1 to 2 nine level). The MG.Si is obtained by reducing a silica rock (SiO₂) by carbon (C). The MG.Si has a p-type conductivity and a resistivity of 0.01 to 0.6 Ωcm and, since the lifetime thereof cannot be measured (0 second level), it cannot be used as a solar power generation material.

Located between SEG.Si and MG.Si is solar cell polycrystalline silicon (SOG.Si). With respect to the impurity total amount level of various elements contained in the SOG.Si, there is no definite standard to date and there is also no dedicated material source.

On the other hand, there is a report about single elements contained in SOG.Si. Various impurity elements were added at the time of manufacturing single-crystal silicon of the CZ method to obtain p-type 0.5 Ωcm wafers and the amounts of the impurity elements that can satisfy a reference value of photoelectric conversion efficiency of 10% or more were derived. In accordance therewith, Ni/5.0 ppm, C/4.2 ppm, Al/0.57 ppm, Cu/0.31 ppm, B/0.3 ppm, Sb/0.06 ppm, Fe/0.023 ppm, P/0.015 ppm, Cr/0.0092 ppm, Ti/0.0001 ppm or less, and Zr, V, and Mg are substantially equal to Ti. However, these values are values in the case where these metal elements are contained in the silicon alone as impurities and thus do not suggest the case where these elements are simultaneously contained in the silicon.

According to results of tests conducted by the present inventors, it has been found that it is not possible to discuss the whole thing by defining the content of each of the individual elements alone. This is because not only the impurity content in MG.Si being a starting material differs depending on a manufacturing place or manufacturer but also impurity contamination due to various elements from reactor members is caused in subsequent reaction processes. Further, not only single-crystal cells but also polycrystalline cells are used as solar power generation cells. The latter may be lower than the former with respect to the purity level.

Among the elements contained in the SOG.Si, those elements that each affect the solar power generation efficiency even in a very small amount are Cr, Ti, Zr, V, and Mg (see the above) and, therefore, if selection is made of reactor members with less content of these elements, the impurity contamination is suppressed.

It takes much time and cost to measure, per material used among mass-produced polycrystalline silicon materials, how it is contaminated with elements. This is not economical.

As a result of diligent study, the present inventors have found that the quality of SOG.Si can be best defined by a conductivity type, a resistivity, and a lifetime. Values thereof are such that the conductivity type is p-type or n-type, the resistivity is 0.3 to 500 Ωcm, and the lifetime is 2 to 500 μsec.

When n-type 2 Ωcm SOG.Si is used and polycrystallized without addition of a doping agent, it is contaminated with p-type impurities from peripheral members of an apparatus in a crystallization process so that p-type crystals are obtained and the resistivity is reduced. A silicon wafer currently used for solar power generation has, regardless of single crystal or polycrystal, a p-type or n-type conductivity, a resistivity of 0.3 to 10 Ωcm, and a thickness of 150 to 350 μm. Therefore, the quality of SOG.Si being a starting material before becoming a wafer is required to be higher than that.

With respect to the quality of SOG.Si for solar power generation, the resistivity is preferably 3 Ωcm or more, regardless of p-type or n-type, in consideration of contamination in the crystallization process. When less than 3 Ωcm, it is difficult to obtain crystals having required properties due to contamination in the subsequent process. The upper limit is 500 Ωcm. Since SOG.Si for IC is n-type with 1000 Ωcm or more, a resistivity range between 500 Ωcm and 1000 Ωcm can be said to be a gray zone. SOG.Si having such a resistivity is expected to exhibit a high photoelectric conversion efficiency but is expensive for solar power generation.

The lifetime is inversely proportional to the metal element impurity content in silicon and thus is shortened as the impurity content increases. The value of the lifetime differs depending on a kind of metal element and content thereof. However, even if the impurity content is large, in the case of an element that does not affect the photoelectric conversion efficiency, the efficiency does not decrease while the lifetime value is small. In the case of polycrystal, the lifetime value is influenced by the sizes of crystal grains. Further, since it is largely influenced by a state of the surface of a measurement sample, a drawback is occurred in that numerical values are largely dispersed. Although, as described above, the lifetime value does not establish a linear correlation with the impurity content as opposed to the resistance value, it is necessary as means for evaluating the ingot properties.

From the foregoing, the lifetime value of SOG.Si is preferably 2 to 500 μsec. When less than 2 μsec, the photoelectric conversion efficiency decreases. The upper limit is 500 μsec. Since an IC ingot has a lifetime of 1000 μsec or more, a lifetime range between 500 μsec and 1000 μsec is a gray zone like the resistivity. SOG.Si having such a lifetime is expected to exhibit a high photoelectric conversion efficiency but is too much for solar power generation. The lifetime of a solar power generation wafer after cell formation is largely improved by diffusion of phosphorus (P) in the cell formation process or a surface stabilization treatment (passivation) by hydrogen so that the value thereof increases. The lifetime of an ingot before the processing is 2 to 50 μsec, while, when it is processed into a wafer and then applied with the processing so as to be a cell, the lifetime increases to 50 to 800 μsec. Therefore, it is not so meaningful to define the lifetime value of the wafer after the processing.

The conventional silicon material for solar power generation is obtained by using scraps secondarily produced from the semiconductor industries as described before, mixing the scraps at a ratio that achieves a required conductivity type and resistivity, and then crystallizing them. The quality (resistivity) required for the scrap is 0.5 Ωcm or more and, on occasion, 1 Ωcm or more regardless of p-type or n-type and the size thereof is larger than an egg. However, not only the resistivity and size differ depending on generation sources but also it is difficult to stably secure the quantity of the scraps. Further, since it is necessary to add a dopant to the scraps so as to achieve a required resistivity, the expensive dopant is required and mixing means is further required for adding the dopant.

In this invention, a control can be executed to enable manufacturing a large amount of solar power generation silicon material having a required quality from the start of thermal decomposition of silane to thereby make the addition of the dopant unnecessary so that crystalline silicon can be manufactured at a low cost. Control objects are a conductivity type, resistivity, and lifetime, which cannot be thought of in the conventional polycrystalline silicon manufacturing method. Like in the conventional technique, there is no intention to refuse mixing materials or scraps having mutually different conductivity types, resistivities, and lifetimes to obtain solar power generation crystals having required properties by adding a dopant when necessary.

In order to produce wafers for solar power generation, SOG.Si is used as a material to obtain single-crystal silicon (CZ or FZ method) or polycrystalline silicon (casting method) and then the obtained silicon is cut into wafers each having a required thickness and size. The wafer is required to have, as its properties, a resistivity of 0.3 to 10 Ωcm regardless of single crystal or polycrystal and p-type or n-type. When the resistivity is less-than 0.3 Ωcm or more than 10 Ωcm, the photoelectric conversion efficiency decreases. Since the lifetime of the wafer largely differs between a value after the slicing and a value after the cell formation as described before, it is difficult to define it unconditionally. Known methods/conditions in this industry can be adopted for a method of manufacturing crystalline silicon for solar power generation (CZ, FZ, or casting method) and a method of processing (slicing) crystalline silicon into wafers and, therefore, no particular means are additionally required.

As described before, the silicon material for solar power generation does not require the semiconductor-grade purity. Further, it is understandable that it is possible to manufacture the inexpensive polycrystalline silicon material and wafer for solar power generation because of the foregoing advantages.

Description will be made as regards specific manufacturing examples according to this invention with a comparative example also given.

### EXAMPLE 1

A 4 mm-square n-type single-crystal Si seed rod with 4.5 Ωcm was set in a gate shape in a quartz bell jar (inner diameter: 120 mm; height: 500 mm) and the bell jar was heated by an external heating device. Herein, the Si seed rod was composed of one lateral rod and two vertical rods and had a height of 245 mm, wherein the lateral rod had a length of 87 mm and the distance between the centers of the vertical rods was 58 mm. The Si seed rod was set in the gate shape by cutting an upper end portion of each vertical rod into a V-shape and then the lateral rod was placed on the V-shaped end portions of the vertical rods. After the temperature of the Si seed rod surface reached 1140° C. as measured by an optical pyrometer, a hydrogen gas was supplied at a flow rate of 11.7 L/min in total for 2 hours. Specifically, a hydrogen gas for bubbling was supplied into a trichlorosilane solution (25° C.) at a flow rate of 0.6 L/min, a hydrogen gas was directly introduced into the reactor at a flow rate of 10.8 L/min, and a reactor peep window hydrogen gas was supplied from a lower part of the reactor toward inner wall surfaces of the reactor at a flow rate of 0.3 L/min. After the lapse of 2 hours, the bubbling hydrogen flow rate in the trichlorosilane was increased to 0.8 L/min (corresponding to vaporization amount of 250 g/hour). The reaction was stopped after the lapse of 8 hours and the deposited Si amount was measured to be 182.2 g. The mass of the Si seed rod before the start of the reaction was 21.27 g and the concentration of B (boron) in the trichlorosilane used was 37 ppb (chemical analysis method). B was analyzed by the chemical analysis method wherein the average value of values obtained by performing the analysis four times was adopted. With respect to the contents of impurities other than B, the content of Fe was 1 ppb or less and the total content of the various other metal impurities was 0.2 ppb or less.

The conductivity type, resistivity, and lifetime of an obtained ingot were measured. In the measurement, a laser light PN checker was used for the conductivity type, a four probe method was used for the resistivity, and a microwave attenuation method was used for the lifetime (use was made of a measurement sample whose surface processing strain was cut by 30 μm through etching and which was washed by clean water). The results were n-type and 5 kΩcm or more (detection limit or more). The average value of the lifetime was 67.2 μsec.

### EXAMPLE 2

Use was made of a 4 mm-square p-type single-crystal Si seed rod with 4.0 Ωcm. By the use of the same trichlorosilane as in Example 1, a test was conducted in the same manner. The amount of silicon after the lapse of 8 hours was 182.3 g.

The conductivity type, resistivity, and lifetime of an obtained ingot were measured. The results were p-type and 270 to 1 kΩcm at a center portion and n-type and 5 kΩcm or more (detection limit or more) at a peripheral portion. The lifetime was low like 15 μsec at the center portion and 57 μsec at the peripheral portion and the average value was 42.0 μsec.

### EXAMPLE 3

Use was made of a 4 mm-square n-type polycrystalline Si seed rod with 4.0 to 5.7 Ωcm made by the casting method and the reaction like in Example 1 was carried out. However, the concentration of B in a trichlorosilane (n=4) was 200 ppb. The conductivity type, resistivity, and lifetime of an obtained ingot were measured. The results are shown in Table 1 below. With respect to the contents of impurities other than B in the trichlorosilane, the content of Fe was 1 ppb and the total content of the various other metal impurities was 0.3 ppb or less.

### EXAMPLES 4 AND 5

Example 4: By the use of a 4 mm-square p-type polycrystalline Si seed rod with 1.3 to 3.2 Ωcm of the casting method and a trichlorosilane having the same concentration as in Example 3, the reaction was carried out for 24 hours. The results are shown in Table 1 below.

TABLE 1

| | Seed Rod | | B in | | | Product | | | |
|---|---|---|---|---|---|---|---|---|---|
| | | Resistivity | SiHCl₃ | Reaction | Yield | | Resistivity | Lifetime | |
| Example | Shape | (Ω cm) | (ppb) | Time (Hr) | (g) | Type | (Ω cm) | (μsec) | Remarks |
| 1 | Single-Crystal | 4.5 | 37 | 8 | 182.2 | n | * | 67.2 | |
| | n-type 4 mm-square | | | | | | | | |
| 2 | Single-Crystal | 4.0 | 37 | 8 | 182.3 | n(P)¹⁾ | * | 42 | |
| | p-type 4 mm-square | | | | | | (270˜1k)²⁾ | | |
| 3 | Polycrystalline | 4.0-5.7 | 200 | 8 | 184.8 | n | 2.5k˜3.1k | 45 | |
| | n-type 4 mm-square | | | | | | | | |
| 4 | Polycrystalline | 1.3-3.2 | 200 | 24 | 644.5 | n(P) | 2.0k˜2.7k | 32.5 | |
| | p-type 4 mm-square | | | | | | (240˜725) | | |
| 5 | Polycrystalline | 4.0-5.7 | 480 | 24 | 644.5 | p | 0.5k˜1.2k | 31.3 | |
| | n-type 4 mm-square | | | | | | | | |
| 6 | Polycrystalline | 0.5-1.2k | 200 | 8 | 184.9 | n | 1.7k˜4.7k | 31 | |
| | n-type 4 mm-square | | | | | | (790˜1300) | | |
| 7 | Single-Crystal | 4.5 | 980 | 8 | 182 | P(n) | 0.4 | 2.1 | Alone x |
| | n-type 4 mm-square | | | | | | | | Mixed OK |
| Comparative | Single-Crystal | 2100 | 1120 | 8 | 182.2 | P(n) | 0.2 | 1.5 | |
| Example | n-type 4 mm-square | | | | | | | | |
| Reference | Single-Crystal | 2100 | 0 or less | 8 | 181.8 | n | * | 1,450 | |
| Example | n-type 4 mm-square | | | | | | | | |

Notes ¹⁾ and ²⁾: Parentheses represent a center portion. * Detection Limit Value or More

Example 5: By the use of the same Si seed rod as in Example 3 and a trichlorosilane having a B concentration of 480 ppb, the reaction was carried out for 24 hours. The results are shown in Table 1 below. With respect to the contents of impurities other than B in the trichlorosilane, the content of Fe was 2 ppb and the total content of the various other metal impurities was 1 ppb or less.

### EXAMPLE 6

An n-type polycrystalline silicon rod obtained in Example 5 was processed into a 4 mm square, which then was used as a Si seed rod. By the use of a trichlorosilane having a B concentration of 200 ppb, the reaction was carried out for 8 hours. The conductivity type, resistivity, and lifetime of an obtained ingot were measured. The results are shown in Table 1 below.

### EXAMPLE 7

By the use of a trichlorosilane having a B concentration of 980 ppb, the reaction was carried out for 8 hours in the same manner as in Example 1. The conductivity type, resistivity, and lifetime of obtained polycrystalline silicon were measured and the results were n-type, 5 Ωcm, and 4.5 μsec in the order named, respectively. By the use of this polycrystalline silicon, polycrystalline silicon for solar power generation was manufactured by the casting method without adding a doping agent. The conductivity type, resistivity, and lifetime of the obtained polycrystalline silicon of the casting method were p-type, 0.4 Ωcm, and 2 μsec in the order named, respectively. Further, the conversion efficiency after cell formation was low like 9.8% and thus it was not usable as a polycrystalline wafer for solar power generation. With respect to the contents of impurities other than B, the contents of Fe, Ni, and Cr were 4.9 ppb, 0.3 ppb, and 0.4 ppb, respectively, and the total content of the various other metal impurities was 0.2 ppb or less.

On the other hand, the obtained polycrystalline silicon and semiconductor-grade polycrystalline silicon obtained in Reference Example were mixed at a ratio of 1:1, thereby manufacturing polycrystalline silicon for solar power generation by the casting method. The properties of the obtained polycrystalline silicon were n-type, 3.5 Ωcm, and 25 μsec and the conversion efficiency after cell formation was 13.7%. From the foregoing, it is understandable that although it is not possible to use the initially obtained polycrystalline silicon alone as a solar power generation material, it is fully usable as the solar power generation material by mixing with the high-purity material.

### EXAMPLE 8

A boron alloy having a B content (0.01 ppb) was added to the polycrystalline silicon (n-type, 5 kΩcm or more) obtained after the reaction time of 8 hours in Example 1, thereby manufacturing p-type polycrystalline silicon with 1.0 Ωcm for solar power generation by the casting method. The lifetime was 17.3 μsec.

The manufactured polycrystalline silicon was sliced into a size (10 mm square×300 μm) and, after etching, a 10 mm-square cell for solar power generation was manufactured. The photoelectric conversion efficiency thereof was measured to be 15.7%.

### EXAMPLE 9

A boron alloy having a B content (0.01 ppb) was added to the n-type polycrystalline silicon (p-type at the center portion) obtained after the reaction time of 24 hours in Example 4, thereby manufacturing p-type polycrystalline silicon with 1.0 Ωcm for solar power generation by the casting method. The lifetime was 16.7 μsec.

The manufactured polycrystalline silicon was sliced into a size (10 mm square×300 μm) and, after etching, a 10 mm-square cell for solar power generation was manufactured. The photoelectric conversion efficiency thereof was measured to be 16.0%.

### EXAMPLE 10

Solar cell polycrystalline silicon was manufactured by the casting method without adding a dopant to the polycrystalline silicon (n-type) obtained after the reaction time of 24 hours in Example 5. The obtained polycrystalline silicon had a p-type conductivity, a resistivity of 0.6 Ωcm, and a lifetime of 17.5 μsec, and the photoelectric conversion efficiency after cell formation was 15.8%.

### EXAMPLE 11

Single-crystal silicon was manufactured by the FZ method without adding a dopant to the polycrystalline silicon rod (n-type) having a diameter of 30.5 mm and a length of 23.0 mm and obtained after the reaction time of 24 hours in Example 5. Various parameters in the FZ method were such that the inner diameter of a reactor was 250 mm, the Ar gas pressure+0.5 atm, the number of crystal revolution 5 rpm, the temperature of a high-frequency induction heating coil 1470±5° C., and the growth rate 2 mm/min. The obtained polycrystalline silicon for solar power generation had a p-type conductivity, a resistivity of 0.9 Ωcm, and a lifetime of 330 μsec, and the photoelectric conversion efficiency after cell formation was 18.5%.

It is understandable from Examples 10 and 11 that the polycrystalline silicon obtained by this invention makes it possible to directly obtain crystals having the solar cell purity without adding the dopant.

### EXAMPLE 12

A rolling process was applied to a lanthanum-doped molybdenum alloy (trade name: TEM manufactured by A.L.M.T. Corporation) to form a hollow pipe having a diameter of 7 mm and this hollow pipe was set in a reactor so as to be used as a heat source. The heat source was set in a gate shape having a height of 170 mm so as to be arranged crosswise to a Si seed rod. Then, by the use of the same Si seed rod as in Example 1, a test was conducted under the same conditions as in Example 1. After a hydrogen gas was substituted for a nitrogen gas in the reactor, the TEM was energized until the temperature inside the reactor reaches 900° C., then the energization was switched to the Si seed rod at 900° C. or higher to heat the surface of the Si seed rod to 1100° C. After the lapse of 5 minutes, a nitrogen gas was introduced into the pipe to cool the TEM to 800° C. or less while the temperature of the Si seed rod was raised to 1150° C. and then a raw material silane gas was immediately supplied to thereby cause a reaction. As a result, Si was deposited/grown on the Si seed rod while Si deposition/growth was not observed on the surface of the TEM. After completion of the reaction, the surface of the TEM was observed but no silicide was recognized so that the TEM was reusable.

An obtained ingot had an n-type conductivity, a resistance of 5 kΩ or more, and a lifetime of 67 μsec. Further, by the use, instead of the TEM, of a highly purified graphite (manufactured by Toyo Tanso Co., Ltd.) having an ash content of 3 ppm or less as a heat source (with no cooling means), a test was likewise conducted. Although an improvement in power source unit was recognized in the initial stage of the reaction, Si was deposited/grown also on the graphite heat rod so that it was not reusable.

In Example 12, the lanthanum-doped molybdenum alloy was used as an example of a metal or alloy having a recrystallization temperature of 1100° C. or more. However, in this invention, as the metal or alloy having the recrystallization temperature of 1100° C. or more, use can be made of W, Ta, Nb, or Mo, or an alloy containing at least one of these metals.

### COMPARATIVE EXAMPLE

By the use of a trichlorosilane having a B concentration of 1120 ppb, the reaction was carried out for 8 hours in the same manner as in Example 1. The conductivity type, resistivity, and lifetime of obtained polycrystalline silicon were measured and the results were p-type, 0.2 Ωcm, and 1.5 μsec in the order named, respectively. By the use of this polycrystalline silicon, polycrystalline silicon for solar power generation was manufactured by the casting method without adding a doping agent. The conductivity type, resistivity, and lifetime of the obtained polycrystalline silicon of the casting method were p-type, 0.4 Ωcm, and 2 μsec in the order named, respectively. Further, the conversion efficiency after cell formation was low like 9.8% and thus it was not usable as a polycrystalline wafer for solar power generation.

With respect to the contents of impurities other than B, the content of Fe was 49 ppb and the total content of the various other metal impurities was 8.0 ppb or less.

### REFERENCE EXAMPLE: SIEMENS METHOD

By the use, instead of the seed rod in Example 1, of a 4 mm-square n-type single-crystal silicon rod (obtained by cutting the high-purity semiconductor polycrystalline silicon obtained by the FZ method into a 4 mm square), polycrystalline silicon was manufactured under the same conditions as in Example 1. The reaction was stopped after the lapse of 8 hours and the deposition amount was measured to be 181.5 g.

The conductivity type, resistivity, and lifetime of an obtained ingot were measured and the results were n-type, 5 kΩcm or more (detection limit or more), and 1450 μsec in the order named, respectively. Therefore, the lifetime was better than the polycrystalline silicon obtained in Example 2 of this invention. These properties were the quality of the semiconductor polycrystalline silicon (SEG.Si) itself, i.e. satisfied the purity of SEG.Si.

As described above, according to this invention, it is possible to directly manufacture a wafer for solar power generation from a silicon material for solar power generation and therefore the cost reduction can be achieved, thereby largely contributing to the field of manufacturing silicon materials for solar power generation.

1. A polycrystalline silicon material for solar power generation, said polycrystalline silicon material being composed of polycrystalline silicon made by supplying a raw material silane gas to a heated silicon seed rod in a sealed reactor at high temperature to thereby thermally decompose or hydrogen-reduce said raw material silane gas, said polycrystalline silicon material having a p-type or n-type conductivity, a resistivity of 3 to 500 Ωcm, and a lifetime of 2 to 500 μsec and being used for manufacturing a silicon wafer for solar power generation.

2. The polycrystalline silicon material for solar power generation according to claim 1, wherein said raw material silane gas is a trichlorosilane or a monosilane and has a concentration of boron of not less than 10 ppb and not more than 1000 ppb.

3. A silicon wafer for solar power generation, comprising a wafer manufactured by crystallizing the polycrystalline silicon material according to claim 1 without adding a doping agent and then slicing it.

4. The silicon wafer according to claim 3, wherein said wafer has a p-type or n-type conductivity and a resistivity of 0.3 to 10 Ωcm.

5. The silicon wafer according to claim 3, wherein said wafer is composed of single-crystal silicon or polycrystalline silicon, said single-crystal silicon being made by a CZ or FZ method as a crystallization method, said polycrystalline silicon being made by a casting method as a crystallization method.

6. The silicon wafer according to claim 5, wherein said single-crystal or polycrystalline silicon wafer has a p-type or n-type conductivity and a resistivity of 0.3 to

7. The polycrystalline silicon material according to claim 1, wherein said silicon seed rod is composed of polycrystalline silicon made from said polycrystalline silicon material for solar power generation.

8. The polycrystalline silicon material according to claim 1, wherein said silicon seed rod is composed of single-crystal silicon or polycrystalline silicon, said single-crystal siliconbeing made from said polycrystalline silicon material for solar power generation by the use of a CZ or FZ method, said polycrystalline silicon being made from said polycrystalline silicon material for solar power generation by the use of a casting method.

9. A method of manufacturing a polycrystalline silicon material for solar power generation, the method comprising the step of supplying a raw material silane gas to a heated silicon seed rod in a sealed reactor at high temperature to thereby thermally decompose or hydrogen-reduce said raw material silane gas, said polycrystalline silicon material having a p-type or n-type conductivity, a resistivity of 3 to 500 Ωcm, and a lifetime of 2 to 500 μsec and being used for manufacturing a silicon wafer for solar power generation.

10. The method according to claim 9, wherein said raw material silane gas is a trichlorosilane or has a monosilane and a concentration of boron of not less than 10 ppb and not more than 1000 ppb.

11. A method of manufacturing a silicon wafer for solar power generation comprising the step of crystallizing the polycrystalline silicon made in the method according to claim 9 without adding a doping agent and then slicing it, thereby manufacturing a wafer.

12. The method according to claim 11, wherein a single-crystal or polycrystalline wafer made in said method has a p-type or n-type conductivity and a resistivity of 0.3 to 10 Ωcm.

13. The method according to claim 11, wherein said wafer is made by the use of the single-crystal silicon or polycrystalline silicon, said single-crystal silicon being made by a CZ or FZ method as a crystallization method, said polycrystalline silicon being made by a casting method as a crystallization method.

14. The method according to claim 13, wherein a single-crystal or polycrystalline wafer made in said method has a p-type or n-type conductivity and a resistivity of 0.3 to 10 Ωcm.

15. The method according to claim 9, wherein said silicon seed rod is made of polycrystalline silicon made from said polycrystalline silicon material for solar power generation.

16. The method according to claim 9, wherein said silicon seed rod is made of single-crystal silicon or polycrystalline silicon, said single-crystal silicon being made from said polycrystalline silicon material for solar power generation by the use of a CZ or FZ method, said polycrystalline silicon being made from said polycrystalline silicon material for solar power generation by the use of a casting method.

17. A method of manufacturing a polycrystalline silicon material for solar power generation, the method comprising the steps of:
using a silicon seed rod made of the polycrystalline silicon material according to claim 1, an internal heating type as a heating type, and a heat source made of a metal, an alloy, or a high-purity graphite, each of the metal and the alloy having a recrystallization temperature of 1100° C. or more, when manufacturing the polycrystalline silicon by supplying the raw material silane gas to the red-hot silicon seed rod in the sealed reactor at the high temperature to thereby thermally decompose or hydrogen-reduce said raw material silane gas.

18. The method according to claim 17, wherein said raw material silane gas is supplied after said heat source is cooled to 900° C. or less.
